(19) United States
(12) Patent Application Publication
(10) Pub. No.: US 2019/0322787 A1
(43) Pub. Date: Oct. 24, 2019

(54) TRIBLOCK COPOLYMER COMPRISING MIDDLE BLOCK AND METHOD FOR PREPARING THE SAME

(71) Applicants: Korea University Research and Business Foundation, Seoul (KR); Institute for Research & Industry Cooperation, Pusan National University, Busan (KR)

(72) Inventors: Joona BANG, Seoul (KR); Sanghoon WOO, Seoul (KR); Youngson CHOE, Busan (KR); June HUH, Seoul (KR); Hyun Suk WANG, Seoul (KR)

(73) Assignees: Korea University Research and Business Foundation, Seoul (KR); Institute for Research & Industry Cooperation, Pusan National University, Busan (KR)

(21) Appl. No.: 16/377,367

(22) Filed: Apr. 8, 2019

(30) Foreign Application Priority Data
Apr. 18, 2018 (KR) 10-2018-0044756

(51) Int. Cl. C08F 297/02; C08L 25/14; C08L 67/04; C08L 69/00; G03F 7/00

(52) U.S. Cl. CPC C08F 297/026; C08L 25/14; B82Y 30/00; C08L 69/00; G03F 7/0002; C08L 67/04

(57) ABSTRACT

Disclosed is a triblock copolymer including two terminal blocks derived from a block copolymer and a middle block incorporated between the terminal blocks. The middle block has a higher surface energy than the terminal blocks. Also disclosed is a method for preparing the triblock copolymer. The preparation method provides a generalized approach that is highly applicable to processes for the mass production of block copolymers and can be applied to various combinations of block copolymers as well as to specific combinations of copolymers. Also disclosed is a method for nanopatterning using the triblock copolymer. The nanopatterning method enables the formation of nanopatterns with sub-10 nm feature size with simple process and reduced cost. Therefore, the nanopatterning method can be widely used in various industrial fields such as semiconductor lithography and memory devices.

### BACKGROUND OF THE INVENTION

### 1. Field of the Invention

The present invention relates to a triblock copolymer including a middle block, a method for preparing the triblock copolymer, and a method for nanopatterning using the triblock copolymer. More specifically, the present invention relates to a triblock copolymer including two terminal blocks derived from a block copolymer and a middle block incorporated between the terminal blocks and having a higher surface energy than the terminal blocks, a method for preparing the triblock copolymer, and a method for nanopatterning using the triblock copolymer.

### 2. Description of the Related Art

Photolithography (top-down approach) is mostly used in mass-production processes but is faced with limitations in reducing the feature size of patterns. In efforts to overcome these limitations, a great deal of research has been reported on nanopatterning (bottom-up approach) using block copolymers (BCPs).

Block copolymer (BCP) nanolithography, a process where BCP self-assembly is used to pattern nanoscale features which are then transferred to an appropriate material, can replace or complement conventional photolithography, the processes of which have become increasingly expensive and difficult, particularly at a feature size less than 10 nm.1-14 The basic strategy of BCP nanolithography, for reducing feature size, is based on the phase behavior of the BCP, which is dictated by two major molecular parameters: the degree of polymerization of the BCP (N) and the interaction parameter between the dissimilar constituent monomers of the BCP (χ).

BCPs phase-separate to form crystal-like, periodic domains when the product χN (=h), a measure for the degree of incompatibility between two blocks, exceeds a certain critical value (typically on the order of 10). The pitch of the periodic structure (L₀) scales as L₀˜h^{1/6}N^{1/2} when h>>10. This indicates that decreasing N is the only practical option for reducing feature size (corresponding to the half pitch, L₀/2), suggesting that χ should be high enough to ensure phase separation of BCPs having small N. In addition, the choice of material for BCP lithography is limited on many occasions by an additional requirement for BCP films, which is that the two bounding surfaces (the underlying substrate and the top, free surface) should be neutral to both blocks of the BCP (i.e., Δγ_{S}=γ_{AS}−γ_{BS}=0, where γ_{AS} (or γ_{BS}) is the interfacial tension between the A (or B) block and the bounding surface) in order to orient pattern features perpendicular to the bounding surfaces. These requirements pose a difficult task for finding an appropriate BCP lithographic system because most polymer pairs with high χ also have high Δγ_{S}.

Currently, the most widely used process for BCP lithography is based on poly(styrene-b-methyl methacrylate) (PS-b-PMMA) films, where the surface neutrality at the air-bound, free surface and at the substrate (with a coated neutral layer) is readily achieved. However, the feature size of the PS-b-PMMA system does not scale down below 11 nm due to the weak χ between the styrene and methyl methacrylate monomers. Some alternative BCP systems, which satisfy both the high χ and the surface neutrality conditions, have been demonstrated either by introducing nonatmospheric neutral surfaces, such as solvent vapor or a top-coat surface, or by synthesizing novel BCPs that have high χ and surface neutrality in the atmospheric environment.

Despite these approaches providing strategic guidelines for sub-10 nm BCP lithography, the selectable BCP systems are limited to a few systems due to the difficulty in fulfilling the aforementioned requirement.

### SUMMARY OF THE INVENTION

Thus, the present inventors have earnestly and intensively conducted research to solve the problems of the prior art. As a result, the present inventors have found that a triblock copolymer in which a short middle block (such as PMAA) is introduced into a block copolymer (such as PS-b-PMMA) and has a higher energy than two terminal blocks of the block copolymer can be used to fabricate vertically orientated nanopatterns with sub-10 nm feature size. The present invention has been achieved based on this finding.

The present invention provides a triblock copolymer including two terminal blocks derived from a block copolymer and a middle block incorporated between the terminal blocks wherein the middle block has a higher surface energy than the terminal blocks.

The present invention also provides a method for nanopatterning using the triblock copolymer.

The present invention also provides a method for preparing a triblock copolymer including introducing a middle block into a block copolymer wherein the middle block has a higher surface energy than two terminal blocks of the block copolymer.

The preparation method of the present invention provides a generalized approach that is highly applicable to processes for the mass production of block copolymers and can be applied to various combinations of block copolymers as well as to specific combinations of copolymers. In addition, the nanopatterning method of the present invention enables the formation of nanopatterns with sub-10 nm feature size with simple process and reduced cost. Therefore, the nanopatterning method of the present invention can be widely used in various industrial fields such as semiconductor lithography and memory devices.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a conceptual diagram showing a triblock copolymer of the present invention in which a short middle block is introduced into a block copolymer and a nanopattern with sub-10 nm feature size formed using the triblock copolymer;

FIG. 2 shows a mechanism for the synthesis of a PS-b-PMAA-b-PMMA triblock copolymer via anionic polymerization;

FIG. 3 shows the GPC traces of (a) SM21, (b) PS-b-PtBMA-b-PMMA with Mₙ=21 kg/mol, and (c) PS-b-PtBMA-b-PMMA with Mₙ=18 kg/mol. Black lines represent final BCPs, and dashed lines represent PS homopolymers;

FIG. 4 shows ¹H NMR spectra of (a) PS-b-PMMA, (b) PS-b-PtBMA-b-PMMA, and (c) PS-b-PMAN-b-PMMA with Mₙ=21 kg/mol in CDCl₃;

FIG. 5 shows FT-IR spectra of (a) PS-b-PtBMA-b-PMMA with Mₙ=21 kg/mol (bottom), anhydride-SHM21-0.6 (middle), and SHM21-0.6 (top), and (b) PS-b-PtBMA-b-PMMA with Mₙ=18 kg/mol (bottom), anhydride-SHM18-0.7 (middle), and SHM18-0.7 (top);

FIG. 6 shows the GPC traces of SHM21-0.6. Black, dashed, and dotted lines represent PS-b-PtBMA-b-PMMA (before deprotection of PtBMA block), PS-b-PMAN-b-PMMA (after deprotection of PtBMA block), and PS-b-PMAA-b-PMMA (after hydrolysis of PMAN block), respectively;

FIG. 7 shows the results of TGA analysis for (a) SM21, (b) PS-b-PtBMA-b-PMMA with Mₙ=21 kg/mol, (c) PS-b-PtBMA-b-PMMA with Mₙ=18 kg/mol. Black lines represent weight percentage and dashed lines represent derivative curves as a function of temperature;

FIG. 8 shows cross-sectional TEM images of (a) SHM21-0.6 and (b) SHM18-0.7 and (c) SAXS traces of SM21 (bottom), SHM21-0.6 (middle), and SHM18-0.7 (top);

FIG. 9 shows cross-sectional TEM images of (a) anhydride-SHM21-0.6 and (b) anhydride-SHM18-0.7 and (c) SAXS intensity profiles of anhydride-SHM21-0.6 (bottom) and anhydride-SHM18-0.7 (top);

FIG. 10 shows the temperature dependence of the SAXS profiles near the primary peaks for (a) SM21, (c) MH14-5.1, and (e) SHM18-0.7 and the calculated temperature dependence of the χ for (b) SM21, (d) MH14-5.1, (f) PS-b-PMAA;

FIG. 11 shows the SAXS intensity profiles of (a) SM21, (b) SHM21-0.6, and (c) SHM18-0.7 with increasing temperature. Insets correspond to the plots of inverse scattering intensity (Iₘ⁻¹) as a function of T⁻¹ for (b) SHM21-0.6 and (c) SHM18-0.7;

FIG. 12 shows the DPLS intensity profiles of (a) SHM21-0.6 (circle) and anhydride-SHM21-0.6 (triangle), and (b) SHM18-0.7 (circle) and anhydride-SHM18-0.7 (triangle);

FIG. 13 shows the SAXS intensity profiles of (a) anhydride-SHM21-0.6 and (b) anhydride-SHM18-0.7 with increasing temperature. Insets correspond to the plots of inverse scattering intensity (Iₘ⁻¹) as a function of T⁻¹ for (a) anhydride-SHM21-0.6 and (b) anhydride-SHM18-0.7;

FIG. 14 shows the results of TGA analysis for PMAA homopolymer (3 kg/mol) under (a) isotherm condition (180° C. (circle), 200° C. (square), 220° C. (triangle) 260° C. (star) for 2 hrs) and (b) heating condition (a heating rate of 0.7° C./min from 175° C. to 280° C.);

FIG. 15 shows the SCFT-computed volume fraction profiles of different monomer types for (a) SHM21-0.6 and for (b) SHM18-0.7 at 180° C.=0.046, χ_{SH}=0.314, and χ_{MH}=0.071). In each plot, the position r is rescaled by the radius of gyration (RG) of the BCP. In (b), the direction of r is chosen to be the direction perpendicular to the lamellar interface. Black lines represent the PS block, dashed lines represent the PMMA block, and dotted lines represents the PMAA block;

FIG. 16 shows top-view SEM images of (a) SHM21-0.6 and (b) SHM18-0.7 thin films on the PS-r-PMMA neutral layer with 20 mol % PS and (c) GI-SAXS intensity profiles of SHM21-0.6 (bottom) and SHM18-0.7 (top). The incidence angle is 0.14°;

FIG. 17 shows top-view SEM images of SHM21-0.6 thin films on PS-r-PMMA neutral layer with (a) 20 mol %, (b) 40 mol %, and (c) 60 mol % PS, and (d) GI-SAXS intensity profiles of these samples; SHM21-0.6 on PS-r-PMMA neutral layer with 60 mol % (bottom line), 40 mol % (middle line), and 20 mol % (top line) PS; and

FIG. 18 shows top-view SEM images of SHM18-0.7 thin films on PS-r-PMMA neutral layer with (a) 20 mol %, (b) 40 mol %, and (c) 60 mol % PS, and (d) GI-SAXS intensity profiles of these samples; SHM18-0.7 on PS-r-PMMA neutral layer with 60 mol % (bottom line), 40 mol % (middle line), and 20 mol % (top line) PS.

### DETAILED DESCRIPTION OF THE INVENTION

The present invention will now be described in more detail.

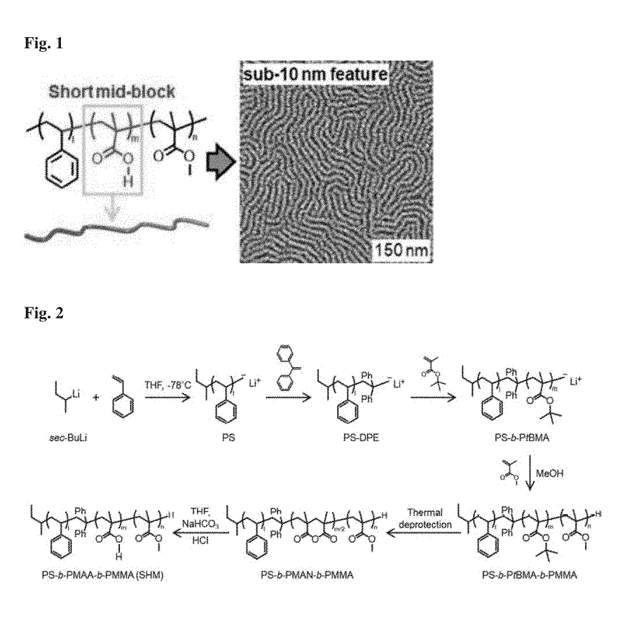

One aspect of the present invention is directed to a novel triblock copolymer for fabricating nanopatterns with sub-10 nm feature size including polystyrene (PS), poly(methyl methacrylate) (PMMA), and short poly(methacrylic acid) (PMAA) introduced at the junction of the polystyrene (PS) and the poly(methyl methacrylate) (PMMA) (FIG. 1).

The present inventors have selected a hydrophilic PMAA block as a middle block for promoting the phase-separation between PS and PMMA blocks as well as preventing its surface coverage and have found that the resulting PS-b-PMAA-b-PMMA triblock copolymers exhibit promoted phase separation as compared to conventional PS-b-PMMA block copolymers.

The middle block has a higher surface energy and is shorter in length than the two terminal blocks.

According to one embodiment of the present invention, the block copolymer may be, for example, polystyrene-block-poly(lactic acid) (PS-b-PLA), polystyrene-block-poly(propylene carbonate) (PS-b-PPC) or poly(styrene-b-methyl methacrylate) (PS-b-PMMA). The block copolymer is preferably poly(styrene-b-methyl methacrylate) (PS-b-PMMA) but is not limited thereto.

The middle block may be, for example, poly(acrylic acid) (PAA), poly(styrene sulfonate) (PSS) or poly(methacrylic acid) (PMAA). The middle block is preferably poly(methacrylic acid) (PMAA) but is not limited thereto.

A further aspect of the present invention is directed to a method for preparing a triblock copolymer by anionic polymerization.

Another aspect of the present invention is directed to a method for nanopatterning using the triblock copolymer. The method of the present invention enables the formation of nanopatterns with sub-10 nm feature size. In contrast, the feature sizes of nanopatterns accessible by conventional methods are limited to >12 nm.

The present invention will be explained in more detail with reference to the following examples and experimental examples. These examples and experimental examples are merely for illustrative purposes and are not intended to limit the scope of the present invention.

### Example 1: Materials

Styrene (99%, Aldrich) was distilled (high-vacuum distillation using Schlenk flask) into a purification flask containing 3-4 ml of 1 M di-n-butylmagnesium in heptane (Aldrich). The heptane was removed by vacuum distillation before introduction of styrene. The monomer was stirred for 1 hr and the above process was repeated. Then purified styrene was distilled into an addition burette. Methyl methacrylate (MMA, 99%, Aldrich) was distilled into a purification flask containing 3-4 ml of 25 wt % trioctylaluminum in hexanes (Aldrich). The hexanes were removed by vacuum distillation before introduction of MMA. A pale yellow color was formed and the monomer was stirred for 1 hr and the above process was repeated. Then purified MMA was distilled into an addition burette. tert-Butyl methacrylate (tBMA, 98%, Aldrich) was distilled into a purification flask containing CaH₂ (powder form, Aldrich). The monomer was stirred for 24 hrs and the procedure was repeated three times. Then purified tBMA was distilled into an addition burette. Tetrahydrofuran (THF, 99.9%, Aldrich) was distilled from sodium-benzophenone ketyl. The purified THF was distilled into an addition solvent flask which has lithium chloride (LiCl, 99.99%, Aldrich) that had been vacuum dried overnight at 110° C. 1,1-Diphenlyethylene (DPE, 97%, Aldrich) was distilled into purification flask containing 2-3 ml of 1.4 M sec-butyllithium in cyclohexane (s-BuLi, Aldrich). The cyclohexane was removed by vacuum distillation before introduction of DPE. A burgundy color was formed and the DPE was stirred for 1 hr and the above process was repeated. Then purified DPE was distilled into a flask and stored in argon purged glove box. s-BuLi was titrated. Methanol (anhydrous, 99.8%, Aldrich), anisole (anhydrous, 99.7%, Aldrich), 2-hydroxyethyl 2-bromoisobutyrate (HEBIB, 95%, Aldrich), N,N,N′,N″,N″-pentamethyldiethylenetriamine (PMDETA, 99%, 3 Aldrich), copper(I) bromide (CuBr, 99.999%, Aldrich), propylene glycol monomethyl ether acetate (PGMEA, 99.5%, Aldrich), sodium bicarbonate (NaHCO₃, Aldrich), and hydrochloric acid (HCl, Aldrich) were used as received without further purification.

### Example 2: Polymer Synthesis and Characterization

2-1: Polymer Synthesis

PS-b-PMMA was synthesized by anionic polymerization. All the glassware was heated at 600° C. for overnight before use. The stirring bars, syringes, and needles were dried at oven and every syringes and needles were purged with argon before use. The solvent was introduced to reactor and cooled down to −78° C. using a dry ice-acetone bath. After temperature equilibration, the s-BuLi (0.9941 ml) was injected into the reactor through septum. Styrene (6.72 g, 64.52 mmol) was added dropwise and bright yellow color appeared. After finishing styrene addition, the polymerization was done for 30 minutes. Afterwards, purified DPE (0.11 ml, n_{DPE}=1.2 n_{sec-BuLi}) was injected into the reactor through the septum and red color appeared. After stirring 30 min, MMA (6.68 g, 66.72 mmol) was added dropwise and the color disappeared. After finishing MMA addition, the polymerization was done for 30 minutes. In order to terminate the reaction, degassed methanol was injected through the septum. All of the above reactions were performed at −78° C. The resulting product was precipitated into methanol, filtered, and freeze-dried from benzene.

PS-b-PMAA-b-PMMAs were synthesized by anionic polymerization and acid deprotection. First, PS-b-P(tBMA)-b-PMMAs were synthesized by anionic polymerization in a similar manner of PS-b-PMMA synthesis. Only difference is adding tBMA monomer between DPE and MMA addition step. After synthesizing PS-b-P(tBMA)-b-PMMAs, thermal acid deprotections were performed. PS-b-P(tBMA)-b-PMMAs were dissolved in THF and placed in Schlenk flasks. The mixtures were purged with argon and the solvent was removed by vacuum. Then the flasks were heated in a vacuum oven at 230° C. for 30 minutes. The resulting anhydride containing PS-b-PMAN-b-PMMA were dissolved in a THF and precipitated into methanol, filtered and dried in vacuum oven. Then dried PS-b-PMAN-b-PMMAs underwent hydrolysis reaction in order to form carboxylic group. PS-b-PMAN-b-PMMAs were dissolved in THF and aqueous NaHCO₃. The reactions were performed at 70° C. for 1 hr and allowed to cool to room temperature. The resulting solutions were treated with 10% HCl for 10 min and were poured into methanol. Then PS-b-PMAA-b-PMMAs were filtered and dried under vacuum at room temperature.

Three different fractions of hydroxyl terminated PS-r-PMMAs were synthesized by ATRP. For hydroxyl terminated PS-r-PMMA with 20 mol % PS content, styrene and MMA were purified by passing through a column filled with alumina and MgSO₄ to remove the inhibitor and water. HEBIB (0.0482 g, 0.228 mmol), styrene (0.9047 g, 8.686 mmol), MMA (7.8275 g, 78.18 mmol) and anisole (8 ml) were added to Schlenk flask reactor which has CuBr (0.0328 g, 0.228 mmol). The solution was mixed and degassed by argon purging and then degassed PMDETA (0.0398 g, 0.228 mmol) was injected to reactor. After 24 hrs of reaction, the mixture was exposed to air and diluted with THF. In order to remove the copper complex, the solution was filtered through an alumina column and precipitated into methanol and dried under vacuum. Other hydroxyl terminated PS-r-PMMAs were synthesized in a similar manner

2-2: Polymer Characterization

The average molecular weights and dispersities (D) of block and random copolymers were measured by gel permeation chromatography (GPC, Waters 1515 pump, Water 2414 refractive index detector). The GPC was equipped with three Styragel HR 0.5, HR 2, HR 4 Columns. The molecular weights are relative to PS standards in THF. The composition of block and random copolymers were characterized by ¹H nuclear magnetic resonance spectra (¹H NMR, VNMRS 500). CDCl₃ was used as solvent. Acid deprotection of tert-butyl group and degree of polymerization (N) of P(tBMA) mid-block were characterized by thermogravimetric analysis (TGA, TA 50) at a heating rate of 5° C./min under N₂ atmosphere. Also in the case of the stability characterization of PMAA homopolymer, the temperature was maintained at 175° C. under N₂ atmosphere for 10 hrs in order to remove bounded water. Then isotherm experiments were performed at various temperatures for 2 hrs under N₂ atmosphere. And increasing temperature experiment was performed at a heating rate of 0.7° C./min from 175° C. to 280° C. under N₂ atmosphere. In order to characterize chemical structural transformation, vibrational spectra were measured by Fourier transform infrared spectroscopy (FTIR, iS10 FTIR) in the attenuated total reflection (ATR) mode. The block copolymer (BCP) samples were deposited onto an Au-coated substrate and obtained 300 scans with an incident angle 80°. The acquired raw data were plotted after baseline correction.

### Example 1: Preparation and Characterization of PS-b-PMAA-b-PMMA Triblock Copolymers

3-1: Preparation of Triblock Copolymers (BCPs)

Two sets of symmetric PS-b-PMAA-b-PMMA (denoted by “SHM”) triBCPs were synthesized by anionic polymerization, where the total molecular weights, Mₙs, of the triBCPs were controlled to 21.3 and 17.5 kg/mol.

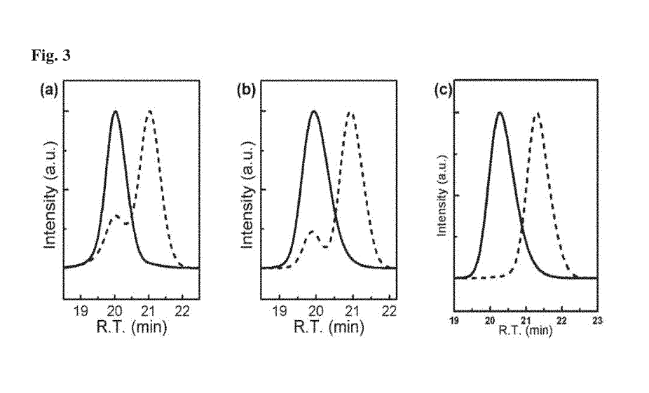

Since the PMAA block cannot be directly incorporated during the synthesis step, poly(tert-butyl methacrylate) (PtBMA) was added as a middle block for later deprotection of the tert-butyl group. The PS block was synthesized first, then the short PtBMA middle block and the PMMA block were sequentially added (FIGS. 2 and 3). The PtBMA middle block was converted to the PMAA block by thermolysis and a subsequent hydrolysis reaction. That is, the final PS-b-PMAA-b-PMMA triBCPs were synthesized by synthesizing the PS block, sequentially adding the PtBMA and PMMA blocks, followed by thermal deprotection and hydrolysis of the PtBMA block.

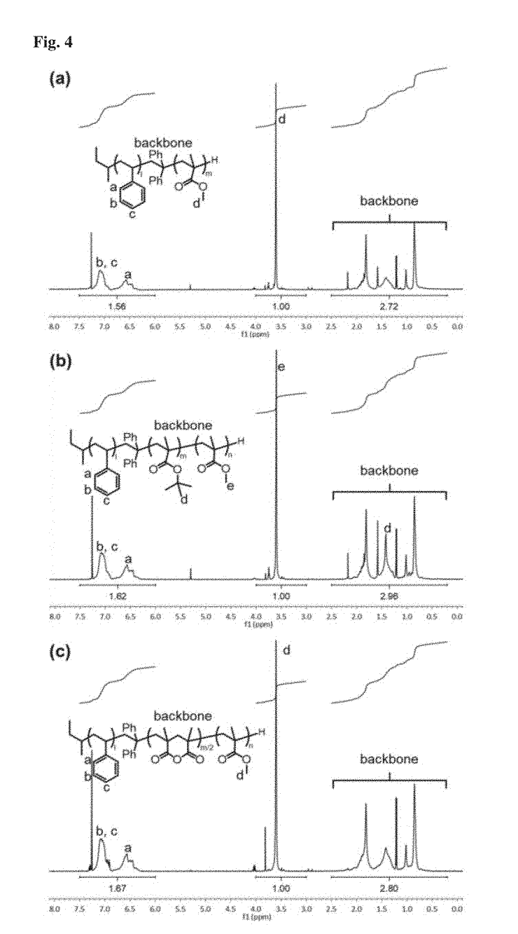

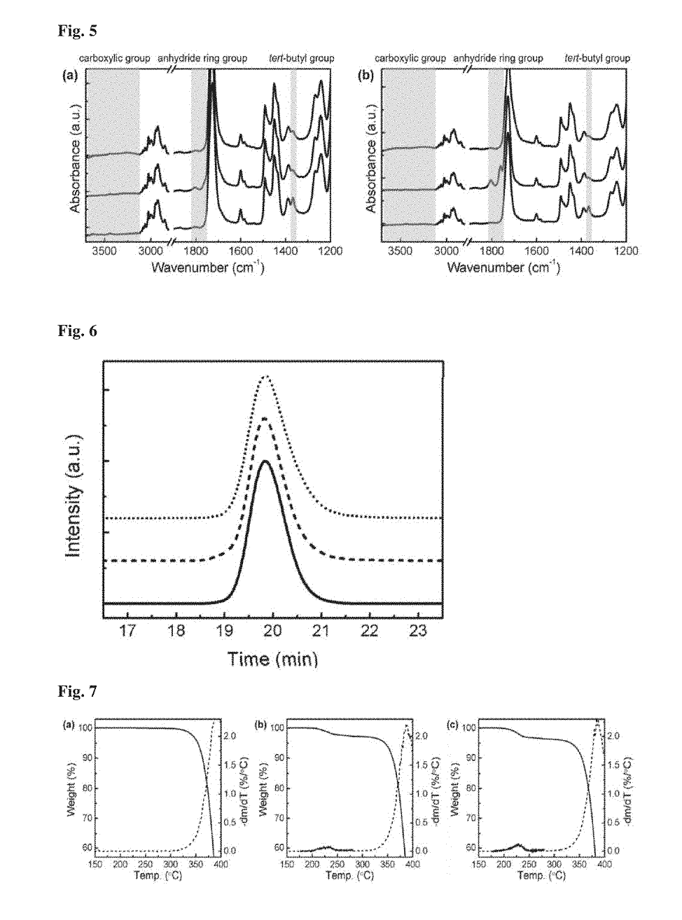

First, the thermolysis of PtBMA resulted in the formation of poly(methacrylic anhydride) (PMAN), as monitored by ¹H NMR and Fourier-transform infrared (FT-IR) spectroscopy. The removal of the tert-butyl group in PtBMA was confirmed by disappearance of the ¹H NMR peak at δ=1.4 ppm, while these protons overlap with the methylene resonances in PS backbone (FIG. 4). From the FT-IR spectra, this reaction was also monitored by the stretching modes of the ester linkage in the anhydride group at 1761 and 1806 cm⁻¹ and a decrease in the C—H bending of tert-butyl group at 1367 cm⁻¹ (this peak overlaps with the bending of methyl group in PMMA; FIG. 5). The anhydride group in the PMAN block was then hydrolyzed to a fully protonated acid group, leading to the PMAA block. This step was observed by a disappearance of the peaks from the ester linkage in the anhydride and the appearance of a small, broad peak at 2500-3500 cm⁻¹, which is due to the vibration mode of the hydroxyl group in the PMAA block. These cross-links were not observed before and after deprotection of PtBMA block (FIG. 6). This is most likely due to the small content of PMAA block (7-8 units per chain) and the intermolecular reaction is further suppressed by steric hindrance by longer PS and PMMA blocks. To confirm the full conversion of tert-butyl group, the weight loss was measured from thermogravimetric analysis (TGA) during the thermolysis of PtBMA block. In this case, the weight loss after thermolysis corresponds to 2.1% and 3.1% for 21 kg/mol and 18 kg/mol PS-b-PtBMA-b-PMMA triBCPs, respectively (FIG. 7), which is consistent with the calculated values for full deprotection of tert-butyl group in PtBMA block. As a result, the Mₙs of the resulting PMAA block were calculated to be 0.6-0.7 kg/mol. To assess the segregation strength of the SHM BCPs, a symmetric PS-b-PMMA (denoted by “SM”) BCP was also synthesized as a control sample with Mₙ=20.8 kg/mol, which is well below the minimum Mₙ (˜28 kg/mol) of a symmetric PS-b-PMMA exhibiting phase separation. Molecular characteristics of the investigated BCP samples and their sample codes are summarized in Table 1.

TABLE 1

| | Mₙ (kg/mol) | | | | total Mₙ, D^{a} |
|---|---|---|---|---|---|
| sample name | PS | PtBMA^{b} | PMAA^{c} | PMMA^{b} | (kg/mol, —) |
| SM21 | 10.4 | | | 10.4 | 20.8, 1.06 |
| SHM21-0.6 | 10.5 | 1.0 | 0.6 | 10.2 | 21.3, 1.08 |
| SHM18-0.7 | 8.6 | 1.2 | 0.7 | 8.2 | 17.5, 1.07 |
| MH14-5.1^{d} | | | 5.1 | 8.5 | 13.1, 1.10 |

^{a}Determined by GPC (eluent: THF 1 mL/min at 40° C., standard: PS).
^{b}Determined by ¹H NMR analysis.
^{c}Calculated from Mₙ of PtBMA.
^{d}Purchased from Polymer Source Inc.

To prepare the BCP solutions, two different SHM triBCPs were dissolved in PGMEA with 0.6˜1.0 wt % and three different hydroxyl terminated PS-r-PMMAs were dissolved in toluene with 0.3 wt %. Silicon substrates were sequentially washed with acetone, isopropanol to clean the surface and to remove any organic contaminants. Hydroxyl terminated PS-r-PMMA neutral layers were spin cast on the substrates for 40 s at 3000 rpm. The samples were thermally annealed at 240° C. for 1 hour under vacuum. In order to remove nongrafted hydroxyl terminated PS-r-PMMA, toluene rinsing was performed. Then the BCP thin films were spin cast from the prepared solutions. The thickness was controlled by adjusting the solution concentration and spin rate. Thin films were annealed at 150° C. for 10 hr.

3-2: Characterization of the Prepared PS-b-PMAA-b-PMMA Triblock Copolymers

3-2-1: Method for Characterization of Triblock Copolymers (BCPs)

Small angle X-ray scattering (SAXS) and grazing incidence-small angle X-ray scattering (GI-SAXS) experiments were carried out at the 4C2 and 9A beamlines at Pohang Accelerator Laboratory (PAL) Korea. Two-dimensional SAXS and GI-SAXS were recorded using a charge-coupled device (CCD) detector positioned at the end of a vacuum flight path. The operating conditions involved a wavelength of 0.7336 Å at the 4C2 and 1.121 Å at 9A, and sample-to-detector distance of 2.0 m at the 4C2 and 2.5 m at 9A. In the case of GI-SAXS, to probe internal film structures, an incidence angle was varied in the range of 0.10°, 0.12°, 0.14°, which was below and above critical angle (0.114°) of PS-b-PMMA. Depolarized light scattering (DPLS) experiments, using a polarized beam from a He—Ne laser source at a wavelength of 632.8 nm, were used to probe the transition temperatures for the BCPs. A sample thickness was set to 0.3 mm in a small bronze template with a 5 mm diameter hole under an ambient condition. The intensity detected at the photodiode was recorded (through A/D converter) as a function of temperature at a heating rate of 0.7° C./min from 120 to 280° C. under N₂ flow. All samples for thermal experiments were prepared using compression-molding at lower than 170° C. immediately after the samples were thermally annealed at 160° C. The heating processes were controlled automatically with a PID temperature controller. Transmission electron microscopy (TEM, Tecnai 20) images were measured by high-resolution TEM at 200 kV. The disk-shaped bulk samples transferred to an epoxy support and embedded samples were microtomed into a section several tens of nanometers thick. The patterns of BCP thin films were characterized by a field emission-scanning electron microscope (FE-SEM, Hitach S-4800) operated at 15 kV. To remove the PMMA block of the pattern, the reactive ion etching (RIE, SNTEK) was conducted with Ar (3 sccm)/O₂ (15 sccm) by a RF power of 10 W at 0.1 torr. The etch rates for PMMA and PS were ˜7.0 nm/sec and ˜1.2 nm/sec, respectively. The etched samples for FE-SEM were coated with a thin Pt film to avoid charging effects.

3-2-2: Determination of χ Using SAXS

Temperature-dependences of χ_{SM}, χ_{SH}, and χ_{MH} were determined by random phase approximation (RPA) analyses using SAXS profiles for SM21, MH14-5.1, and SHM18-0.7 BCP samples, respectively. The RPA equations for AB binary system and for ABC ternary system are given by

$$\begin{matrix}{I}_{2 , AA} ( q ) = \frac{{K}_{2}}{Γ ( q ) - 2 {𝒳}_{AB}} & ( 1 ) \\ {I}_{3 , AA} ( q ) = \frac{{K}_{3} {F}_{AA} ( q )}{Δ ( q )} . & ( 2 )\end{matrix}$$

Here I_{2,AA}(q) and I_{3,AA}(q) are the scattering function in the binary system and in the ternary system, respectively, and K₂ and K₃ are their proportionality constants (which are unimportant in the fitting process), and Γ(q), F_{AA}(q), and Δ(q) are the functions expressed in terms of intrachain monomer density correlation functions g_{αβ}(q) in the ideal state, which are given as

$$\begin{matrix}Γ ( q ) = \frac{{g}_{AA} ( q ) + {g}_{BB} ( q ) + 2 {g}_{AB} ( q )}{{g}_{AA} ( q ) {g}_{BB} ( q ) - {g}_{AB}^{2} ( q )} & ( 3 ) \\ {F}_{AA} ( q ) = {C}_{ABC} ( q ) - 2 {𝒳}_{BC} A ( q ) & ( 4 ) \\ Δ ( q ) = S ( q ) + {\sum }_{( αβγ )} [ 2 {𝒳}_{ α β} {B}_{αβγ} ( q ) - A ( q ) ( {𝒳}_{αβ}^{2} - {𝒳}_{αβ} {𝒳}_{αγ} ) ] & ( 5 ) \\ A ( q ) = {g}_{AA} ( q ) {g}_{BB} ( q ) {g}_{CC} ( q ) + 2 {g}_{AB} ( q ) {g}_{AC} ( q ) {g}_{BC} ( q ) - [ {g}_{BC}^{2} ( q ) {g}_{AA} ( q ) + {g}_{AC}^{2} ( q ) {g}_{BB} ( q ) + {g}_{AB}^{2} ( q ) {g}_{CC} ] & ( 6 ) \\ {B}_{αβγ} ( q ) = {g}_{αβ}^{2} ( q ) + {g}_{αβ} ( q ) [ {g}_{αγ} ( q ) + {g}_{βγ} ( q ) + {g}_{γγ} ( q ) ] - {g}_{α α} ( q ) {g}_{ββ} ( q ) - {g}_{αα} ( q ) {g}_{βγ} ( q ) - {g}_{ββ} ( q ) {g}_{αγ} ( q ) - {g}_{αγ} ( q ) {g}_{βγ} ( q ) & ( 7 ) \\ {C}_{ABC} ( q ) = {g}_{AA} ( q ) ⌊ {g}_{BB} ( q ) + {g}_{CC} ( q ) + 2 {g}_{BC} ( q ) ⌋ - {⌊ {g}_{AB} ( q ) + {g}_{AC} ( q ) ⌋}^{2} & ( 8 ) \\ S ( q ) = {g}_{AA} ( q ) + {g}_{BB} ( q ) + {g}_{CC} ( q ) + 2 [ {g}_{AB} ( q ) + {g}_{BC} ( q ) + {g}_{AC} ( q ) ] & ( 9 )\end{matrix}$$

where (αβγ)∈{(ABC),(BCA),(CAB)}.

The monomer density correlation functions g_{αβ}(q)(αβ=AA/BB/AB for diblock copolymer, αβ=AA/BB/CC/AB/BC/AC for ABC triblock copolymer) are given as

$$\begin{matrix}{g}_{αβ} ( q ) = \{ \begin{matrix}\frac{2 \overline{N} {f}_{α}^{2}}{{x}_{α}^{2}} [ {x}_{α} - 1 + u ( {λ}_{α} , {x}_{α} ) ] & if α β = AA / BB / CC \\ \frac{\overline{N} {f}_{α} {f}_{β}}{{x}_{α} {x}_{β}} [ 1 - u ( {λ}_{α} , {x}_{α} ) ] [ 1 - u ( {λ}_{β ,} {x}_{β} ) ] & if α β = AB / BC \\ \begin{matrix}\frac{\overline{N} {f}_{α} {f}_{β} u ( {λ}_{α} , {x}_{α} )}{{x}_{α} {x}_{β}} [ 1 - u ( {λ}_{α} , {x}_{α} ) ] \\ [ 1 - u ( {λ}_{β} , {x}_{β} ) ]\end{matrix} & if α β = AC\end{matrix} & ( 10 ) \\ \overline{N} = \frac{{\sum }_{α} {υ}_{α} {N}_{α}}{{( {Π}_{α} {υ}_{α} )}^{1 / n}} & ( 11 ) \\ u ( {λ}_{α} , {x}_{α} ) = \{ \begin{matrix}exp ( - {x}_{α} ) & if {λ}_{α} = 1 \\ {[ {x}_{α} ( {λ}_{α} - 1 ) + 1 ]}^{- 1 / ( {λ}_{α} - 1 )} & if {λ}_{α} \neq 1\end{matrix} & ( 12 )\end{matrix}$$

where f_{α} is the volume fraction of α-monomer, x_{α}=R²_{G,α}q²,R_{G,α} is the root mean square radius of gyration of α-block, N_{α} is the degree of polymerization of α-block, υ_{α} is the molar volume of α-monomer, n is the number of component types (n=2 for binary system and n=3 for ternary system) and λ_{α} is dispersity of the molecular weight of α-block.

The molecular parameters used for fitting SAXS profiles of SM21, MH14-5.1, and SHM18-0.7 BCP samples are listed in Table 2. The values of χ_{SM}, χ_{SH}, and χ_{MH} at each temperature were determined from the best fits between the experimental and theoretical relative scattering distributions, and the temperature dependences were obtained by linear regressions using the relation χ=a+b/T where a, b are constants characterizing interaction between monomer pair.

TABLE 2

| | N_{S} | N_{H} | N_{M} | ƒ_{S} | ƒ_{H} | ƒ_{M} | υ_{S}^{a} | υ_{H}^{a} | υ_{M}^{a} | λ_{S} | λ_{H} | λ_{M} |
|---|---|---|---|---|---|---|---|---|---|---|---|---|
| SM21 | 100 | — | 104 | 0.53 | — | 0.47 | 100 | — | 84.7 | 1.05 | — | 1.19 |
| MH14-5.1 | — | 59 | 85 | — | 0.36 | 0.64 | — | 67 | 84.7 | — | 1.10 | 1.22 |
| SHM18-0.7 | 83 | 14 | 82 | 0.51 | 0.06 | 0.43 | 100 | 67 | 84.7 | 1.05 | 1.76 | 1.27 |

^{a}Molar volume in unit of cm³/mol

3-2-3: Theoretical Calculation of Volume Fraction Profiles of Monomer Types Using SCFT

Volume fraction profiles of different monomer types for SM21 and for SHM21-0.6 were obtained theoretically by SCFT computations in 2-dimenisonal L×L lattice using a combinatorial screening algorithm in real space. For all computations, the lattice size was chosen as L=7 R_{G} with a unit lattice spacing b=(6R²_{G}/N)^{1/2}. The molecular parameters for SM21 and SHM21-0.6 were given according to Table 2 with an assumption that both systems are monodisperse in composition as well as in molecular weight. The pairwise χ values, determined from SAXS profiles, are used as inputs into SCFT equations (χ_{SM}=0.046, χ_{SH}=0.314, and χ_{MH}=0.071 at 180° C.).

3-2-4: Results of Characterization of BCPs

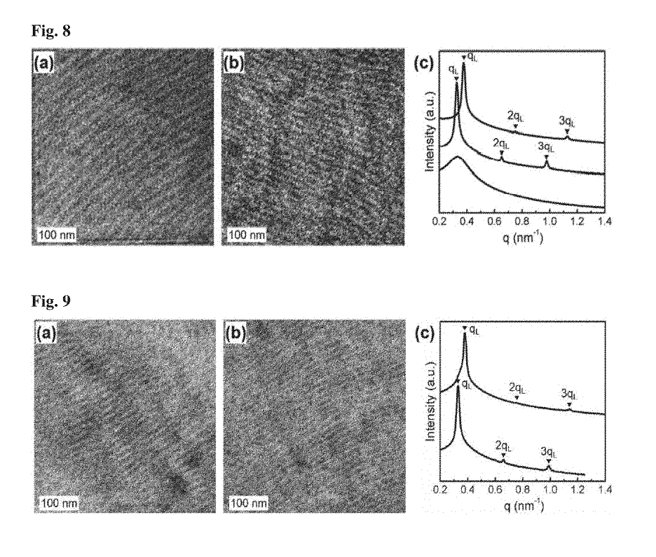

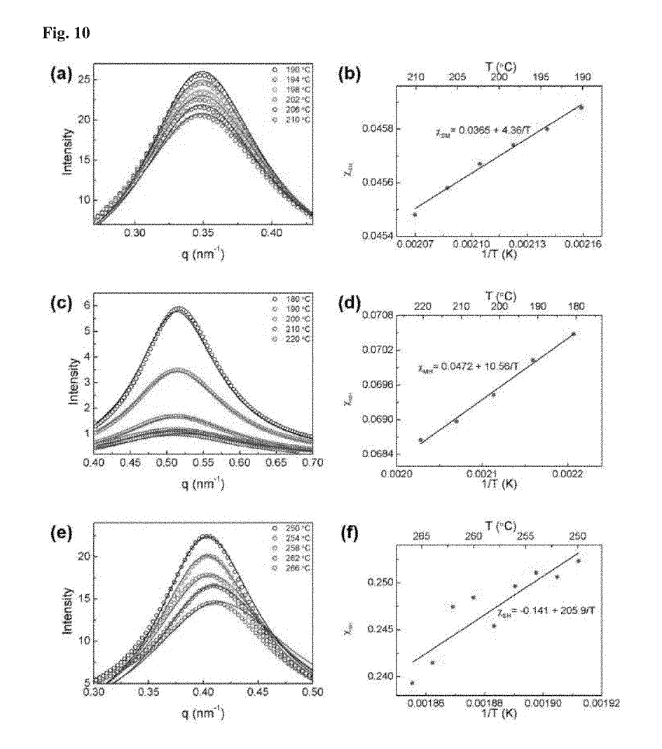

To compare the segregation behaviors between the SHM and SM BCPs, the bulk morphologies were characterized by transmission electron microscopy (TEM) and small-angle X-ray scattering (SAXS). The powder samples were filled in a disk-shaped brass mold and annealed at 180° C. for at least 1 day. For SHM21-0.6 and SHM18-0.7, lamellar morphologies were clearly observed in the TEM images, exhibiting the distinct contrast between bright PMMA and dark PS microdomains ((a) and (b) of FIG. 8), and from the Bragg reflections at q/q*=1:2:3 in the SAXS traces ((c) of FIG. 8). The Los of SHM21-0.6 and SHM18-0.7 were estimated from the first order reflections at q*=0.3258 nm⁻¹ and 0.3769 nm⁻¹, corresponding to L₀=19.3 and 16.7 nm, respectively. The morphology of the triBCP samples before hydrolysis, which are denoted as anhydride-SHM21-0.6 and anhydride-SHM18-0.7, was examined. These samples also exhibited well-ordered lamellar morphologies with nearly the same domain spacing of L₀=19.1 and 16.5 nm, respectively (FIG. 9). In contrast, SM21 BCP sample shows no phase-separated morphology as evident from SAXS profile ((c) of FIG. 8). This is also expected from the estimated value of χN(=9.4 at 180° C.) lower than the critical value of 10.5 where N=204 and χ=0.0365+4.36/T obtained from fitting of SAXS results for SM21 was used. The detailed description for the determination of χ and the used molecular parameters were documented in Table 2 and FIG. 10.

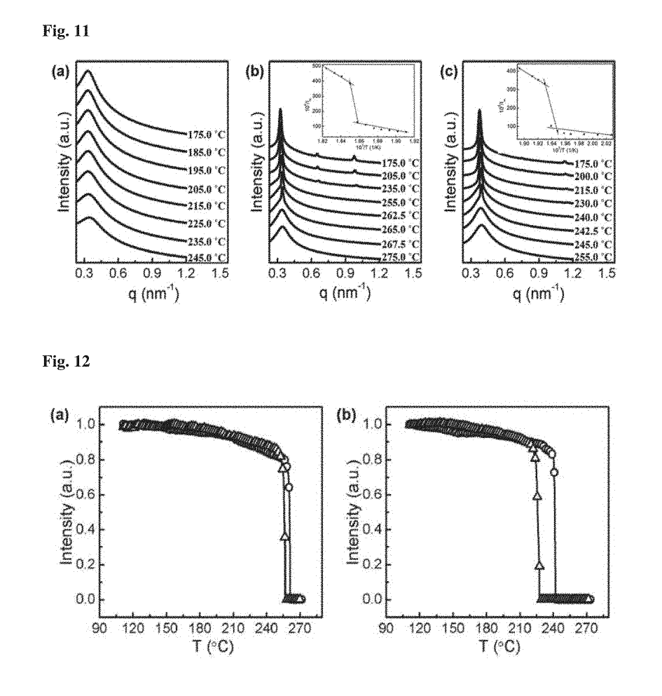

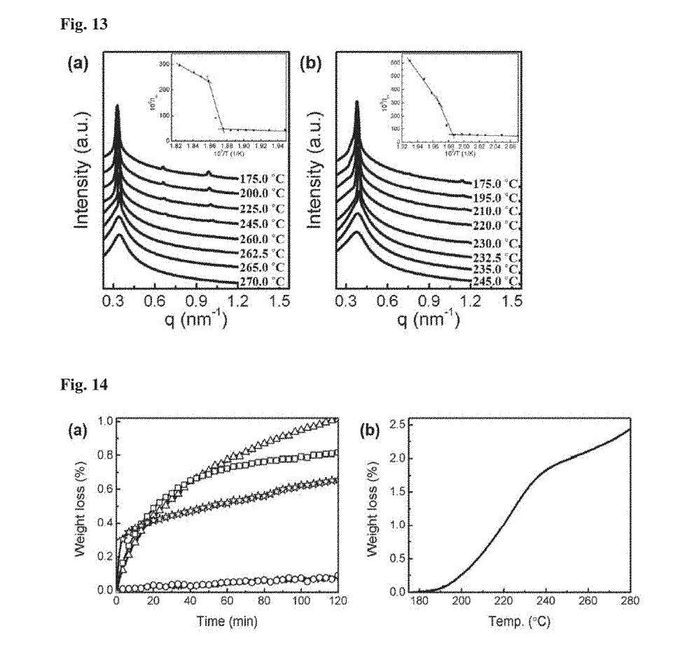

The phase-separation tendencies of these BCPs were further investigated by examining the order-disorder transition temperature, T_{ODT}, from SAXS and depolarized light scattering (DPLS). The lamellar morphologies in SHM21-0.6 and SHM18-0.7 persist up to above 200° C., whereas SM21 exhibits a disordered state over the entire temperature range. The T_{ODTS} from the SAXS measurements were 267.5° C. for SHM21-0.6 and 245° C. for SHM18-0.7 (FIG. 11), which were in good agreement with the DPLS measurements (FIG. 12). Slightly lower T_{ODTS} were observed for the anhydride-SHMs (FIGS. 12 and 13). These measurements indicate that the phase behaviors and segregation strength of the SHM triBCPs before and after hydrolysis are quite similar, despite the difference in chemical structure, and suggest that both PMAA and PMAN effectively strengthen the weak repulsion between the terminal PS and PMMA, thus, promoting phase-separation between them. Since the T_{ODTS} of all BCP samples were observed above 190° C., the degree of cyclodehydration for PMAA homopolymer was examined using TGA at either isothermal (180, 200, 220, and 260° C.) or gradual heating conditions (same as T_{ODT} measurement from SAXS). As a result, the weight loss was estimated as less than ˜2.0 wt % compared to the theoretical value of 10.46 wt % for full conversion. Thus, less than 20% of the PMAA would be dehydrated under our experimental conditions (FIG. 14).

The phase behavior of the SHM triBCP, which depends on three possible pairwise interaction parameters, was analyzed theoretically by random phase approximation (RPA) and self-consistent field theory (SCFT).

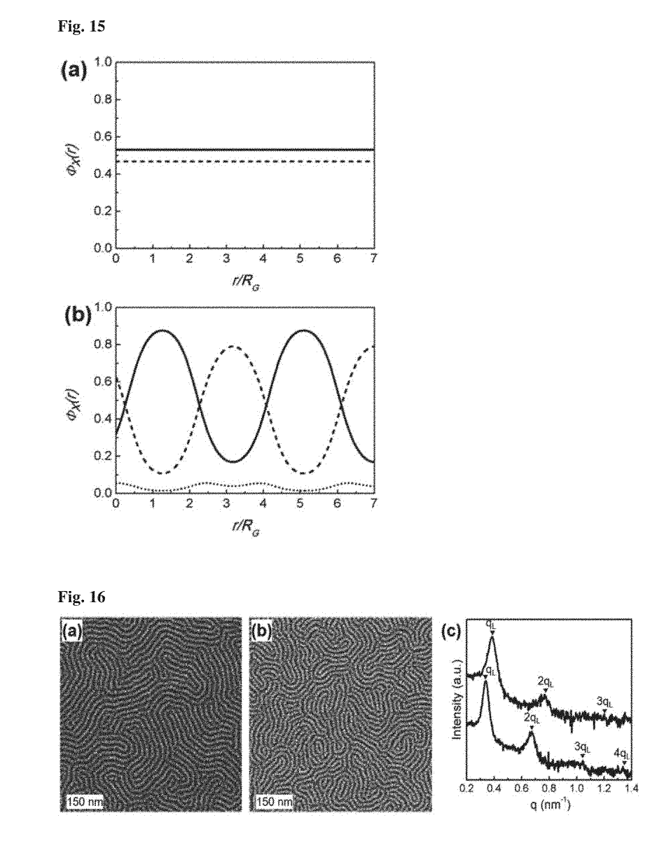

The RPA analyses, using SAXS measurements for the SM, MH, and SHM BCP samples, estimated the three binary interaction parameters and their temperature-dependences: χ_{SM}=0.0365+4.36/T, χ_{SH}=−0.141+205.9/T, and χ_{MH}=0.0472+10.56/T (FIG. 10). The subscripts SM, SH, and MH for χ represent the monomer pairs permuted from styrene (S), methacrylic acid (H), and methyl methacrylate (M), and T is the thermodynamic temperature. In this case, the interaction parameter between styrene and methacrylic acid is considerably larger than the other two parameters. For instance, the interaction parameters estimated at 180° C. are given as χ_{SM}=0.046, χ_{SH}=0.314, and χ_{MH}=0.071, revealing that the promotion of phase-separation in the case of the SHM triBCP is driven largely by a strong, repulsive interaction between styrene and methacrylic acid. The monomer density profiles, which were computed for SM21 and SHM21-0.6 at 180° C. using SCFT, also confirm that phase-separation occurs for SHM21-0.6, whereas SM21 remains homogeneous under the same thermodynamic condition (FIG. 15).

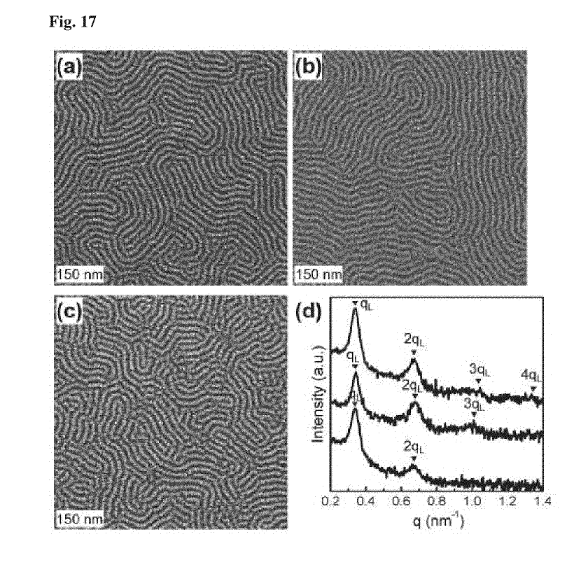

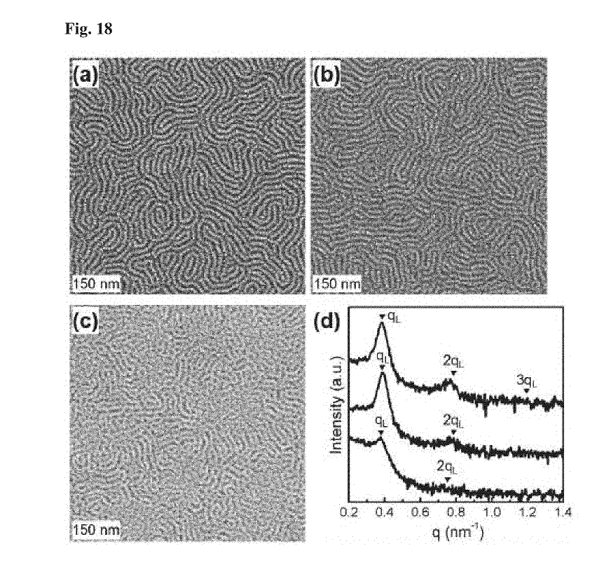

To examine the thin film behaviors of the SHM21-0.6 and SHM18-0.7 triBCPs, the SHM thin films, with thicknesses ˜1 L₀, were prepared on silicon substrates. The surface of the substrates was neutralized with hydroxyl-terminated PS-r-PMMA random copolymers. The PS contents in the PS-r-PMMA were controlled at 20 mol %, 40 mol %, and 60 mol % in order to optimize the neutral condition for the SHM triBCPs. The films were thermally annealed at 150° C. for 10 h and the PMMA block was selectively removed by reactive ion etching with oxygen and argon gas. From the top-view SEM images and grazing incidence small-angle X-ray scattering (GI-SAXS) profiles (FIG. 16), the films exhibit well-ordered nanopatterns with lamellar microdomains oriented perpendicular to the substrates. The domain spacing of the SHM21-0.6 and SHM18-0.7 thin films are 18.6 and 16.2 nm, respectively, consistent with those of bulk samples and corresponding to the sub-10 nm nanopatterns with a feature size of 9.3 and 8.1 nm, respectively. As to the neutral condition of the SHM triBCPs, it was found that better ordering of the lamellae was observed on the PS-r-PMMA neutral layer with 20 mol % and 40 mol % PS, while some defects were present on the 60 mol % PS-r-PMMA neutral layer (FIGS. 17 and 18). This can be attributed to the PMAA middle block, which changes the neutral condition toward more hydrophilic than the pristine PS-b-PMMA BCPs, possibly revealing high asymmetry between χ_{SH} and χ_{MH}. The perpendicular lamellar orientation was attained without additional top coating despite the surface energy imbalance between the middle PMAA block and the terminal blocks. In this case, the top layer, covered with lower-surface energy PS and PMMA blocks, assists the formation of a PS/PMMA interface perpendicular to the film direction.

What is claimed is:

1. A triblock copolymer comprising two terminal blocks derived from a block copolymer and a middle block incorporated between the terminal blocks wherein the middle block has a higher surface energy than the terminal blocks.

2. The triblock copolymer according to claim 1, wherein the middle block is shorter in length than the two terminal blocks.

3. The triblock copolymer according to claim 1, wherein the block copolymer is poly(styrene-b-methyl methacrylate) (PS-b-PMMA), polystyrene-block-poly(lactic acid) (PS-b-PLA) or polystyrene-block-poly(propylene carbonate) (PS-b-PPC).

4. The triblock copolymer according to claim 1, wherein the middle block is poly(methacrylic acid) (PMAA), poly(acrylic acid) (PAA), poly(styrene sulfonate) (PSS).

5. A method for preparing a triblock copolymer comprising introducing a middle block into a block copolymer wherein the middle block has a higher surface energy than two terminal blocks of the block copolymer.

6. The method according to claim 5, wherein the middle block is shorter in length than the two terminal blocks.

7. The method according to claim 5, wherein the block copolymer is poly(styrene-b-methyl methacrylate) (PS-b-PMMA), polystyrene-block-poly(lactic acid) (PS-b-PLA) or polystyrene-block-poly(propylene carbonate) (PS-b-PPC).

8. The method according to claim 5, wherein the middle block is poly(methacrylic acid) (PMAA), poly(acrylic acid) (PAA), poly(styrene sulfonate) (PSS).

9. The method according to claim 5, wherein the triblock copolymer is synthesized by anionic polymerization.

10. A method for nanopatterning using the triblock copolymer according to claim 1.

11. The method according to claim 10, wherein the method enables the formation of nanopatterns with sub-10 nm feature size.
